(19) United States
(12) Patent Application Publication
(10) Pub. No.: US 2026/0302125 A1
(43) Pub. Date: Oct. 1, 2026

(54) System and Method for Extending Faraday Setup Cup Life Time by Scanning Ion Beam during Setup

(71) Applicant: Applied Materials, Inc., Santa Clara, CA (US)

(72) Inventors: Robert C. Lindberg, Rockport, MA (US); Joseph C. Olson, Beverly, MA (US); Christopher W. Campbell, Newbury, MA (US); Tyler Wills, Marblehead, MA (US); Eric D. Wilson, Rockport, MA (US); Freddy Elias Touma, Boston, MA (US); Philip Layne, Salem, MA (US); Shardul S. Patel, Chelmsford, MA (US)

(21) Appl. No.: 19/293,381

(22) Filed: Aug. 7, 2025

Related U.S. Application Data
(60) Provisional application No. 63/777,813, filed on Mar. 26, 2025.

(51) Int. Cl. H01J 37/147; H01J 37/153; H01J 37/244; H01J 37/317

(52) U.S. Cl. CPC H01J 37/1474; H01J 37/153; H01J 37/244; H01J 37/3171; H01J 2237/004; H01J 2237/24405; H01J 2237/24564

(57) ABSTRACT

A system and method for extending the life of a current sensor that is disposed in the path of the ion beam during the configuration and calibration procedure is disclosed. Rather than maintaining the ion beam in a stationary position during the configuration and calibration procedure, the ion beam is moved in the width direction. In this way, a greater amount of the surface of the current sensor is exposed to the beam and the beam current is no longer focused at a single location during the configuration and calibration procedure. This movement of the ion beam reduces thermal stress and sputtering of the current sensor, extending its life.

This application claims priority of U.S. Provisional Patent Application Serial No. 63/777,813, filed Mar. 26, 2025, the disclosure of which is incorporated herein by reference in its entirety.

### FIELD

Embodiments of the present disclosure relate to a system and method for extending the life of a Faraday setup cup, which is used to configure and calibrate the ion implanter.

### BACKGROUND

Ion implantation is a common technique to introduce impurities into a workpiece to affect the conductivity of portions of that workpiece.

In some systems, a spot ion beam is scanned in a scan direction across the workpiece to implant the ions. The scan speed may determine the amount of ions that each portion of the workpiece receives. For example, at higher scan speeds, the beam current of an area is reduced, since the ion beam spends less time over this area. Lower scan speeds allow more ions to be implanted in an area.

In other systems, a ribbon ion beam is used, wherein the ion beam that is extracted from the ion source has a width much greater than its height.

In both embodiments, the workpiece is typically translated to allow the entirety of the workpiece to be exposed to the ion beam.

Prior to implantation, the ion implanter is typically configured and calibrated. This may be done by introducing one or more current sensors, which may be Faraday sensors, in the path of the ion beam. The beam current may be measured using these current sensors, and the ion source, its extraction optics and other components may be tuned to achieve the desired beam current. This configuration and calibration procedure may be time consuming, during which time the ion beam is directed at the current sensor. This may cause the current sensor to increase in temperature, and may ultimately result in cracking or other failures.

Therefore, it would be advantageous if there were a system and method that allowed the configuration and calibration of the ion implanter to occur, but did not cause the failure of the current sensor due to extended exposure to the ion beam.

### SUMMARY

A system and method for extending the life of a current sensor that is disposed in the path of the ion beam during the configuration and calibration procedure is disclosed. Rather than maintaining the ion beam in a stationary position during the configuration and calibration procedure, the ion beam is moved in one or more directions. In this way, a greater amount of the surface of the current sensor is exposed to the ion beam and the beam current is no longer focused at a single location during the configuration and calibration procedure. This movement of the ion beam reduces thermal stress and sputtering of the current sensor, extending its life.

According to one embodiment, an ion implantation system is disclosed. The ion implantation system comprises an ion source from which a spot beam is extracted; a scanner which scans the spot beam in a scan direction to create a scanned spot beam; a workpiece holder; a retractable current sensor, disposed between the scanner and the workpiece holder, having a retracted position, used during normal operation and an inserted position, wherein the retractable current sensor is in a path of the spot beam and which is used during a configuration and calibration procedure; and a controller, wherein the controller creates relative movement between the spot beam and the retractable current sensor during the configuration and calibration procedure, measures a current detected by the retractable current sensor and uses the measured current to adjust one or more components in the ion implantation system to create a spot beam having a desired beam current. In some embodiments, the controller moves the retractable current sensor to the inserted position and controls the scanner to scan the spot beam in the scan direction during the configuration and calibration procedure. In some embodiments, the retractable current sensor is attached to an actuator, and the controller moves the retractable current sensor to the inserted position and controls the actuator to move the retractable current sensor in the scan direction during the configuration and calibration procedure. In some embodiments, the controller varies one or more parameters associated with the ion source based on the current detected by the retractable current sensor. In some embodiments, the ion implantation system comprises extraction optics disposed outside the ion source, and the controller varies one or more parameters associated with the extraction optics based on the current detected by the retractable current sensor. In some embodiments, the retractable current sensor comprises a graphite surface which collects the current. In certain embodiments, the scanner scans the spot beam in the scan direction during the configuration and calibration procedure and the graphite surface is sufficiently large such that an entirety of the scanned spot beam strikes the graphite surface. In certain embodiments, the scanner scans the spot beam in the scan direction during the configuration and calibration procedure; the graphite surface has a dimension in the scan direction that is smaller than the scanned spot beam, and the controller adjusts the current detected to compute an actual beam current, based on a percentage of time that the scanned spot beam strikes the graphite surface. In some embodiments, the scanner scans the spot beam in the scan direction during the configuration and calibration procedure; the retractable current sensor comprises a plurality of graphite surfaces, and the controller sums the current detected by each of the plurality of graphite surfaces to compute an actual beam current. In some embodiments, the controller converts the current detected by the retractable current sensor into an equivalent current, which is defined as a current detected if the spot beam and retractable current sensor were both stationary. In some embodiments, the ion implantation system comprises a corrector magnet disposed between the scanner and the workpiece holder, and the retractable current sensor is disposed between the scanner and the corrector magnet.

According to another embodiment, an ion implantation system is disclosed. The ion implantation system comprises an ion source from which a ribbon ion beam is extracted; a mass resolving device having a mass resolving aperture; a dithering magnet, located downstream from the mass resolving device, which scans the ribbon ion beam in a width direction to create a dithered ion beam; a workpiece holder; a retractable current sensor, disposed between the dithering magnet and the workpiece holder, having a retracted position, used during normal operation and an inserted position, wherein the retractable current sensor is in a path of the ribbon ion beam and which is used during a configuration and calibration procedure; and a controller, wherein the controller creates relative movement between the ribbon ion beam and the retractable current sensor during the configuration and calibration procedure, measures a current detected by the retractable current sensor and uses the measured current to adjust one or more components in the ion implantation system to create a ribbon ion beam having a desired beam current. In some embodiments, the controller moves the retractable current sensor to the inserted position and controls the dithering magnet to dither the ribbon ion beam during the configuration and calibration procedure. In some embodiments, the controller varies one or more parameters associated with the ion source based on the current detected by the retractable current sensor. In some embodiments, the ion implantation system comprises extraction optics disposed outside the ion source, and the controller varies one or more parameters associated with the extraction optics based on the current detected by the retractable current sensor. In some embodiments, the retractable current sensor comprises a graphite surface which collects the current. In certain embodiments, the dithering magnet dithers the ribbon ion beam in the width direction during the configuration and calibration procedure and the graphite surface is sufficiently large such that an entirety of the dithered ion beam strikes the graphite surface. In certain embodiments, the dithering magnet dithers the ribbon ion beam in the width direction during the configuration and calibration procedure; the graphite surface has a dimension in the width direction that is smaller than the dithered ion beam, and the controller adjusts the current detected to compute an actual beam current, based on a percentage of time that the dithered ion beam strikes the graphite surface. In some embodiments, the controller converts the current detected by the retractable current sensor into an equivalent current, which is defined as a current detected if the ribbon ion beam and retractable current sensor were both stationary.

According to another embodiment, an ion implantation system is disclosed. The ion implantation system comprises an ion source from which an ion beam is extracted; a scanning component which scans the ion beam in a scan direction; a workpiece holder that moves in a second direction perpendicular to the scan direction; a retractable current sensor, disposed between the scanning component and the workpiece holder, having a retracted position, used during normal operation and an inserted position, wherein the retractable current sensor is in a path of the ion beam and which is used during a configuration and calibration procedure; and a controller, wherein the controller creates relative movement between the ion beam and the retractable current sensor during the configuration and calibration procedure, measures a current detected by the retractable current sensor and adjusts at least one parameter of the ion implantation system based on the current detected. In some embodiments, the scanning component comprises an electrostatic scanner. In some embodiments, the scanning component comprises a magnet. In some embodiments, the at least one parameter is associated with the ion source. In some embodiments, the ion implantation system comprises extraction optics to extract the ion beam from the ion source, and the at least one parameter is associated with the extraction optics. In some embodiments, the ion implantation system comprises an acceleration stage to change an energy of the ion beam, and the at least one parameter is associated with the acceleration stage. In some embodiments, the retractable current sensor is disposed immediately after the scanning component.

### BRIEF DESCRIPTION OF THE FIGURES

For a better understanding of the present disclosure, reference is made to the accompanying drawings, which are incorporated herein by reference and in which:

FIG. 1 is an ion implanter that utilizes a spot beam according to one embodiment; and

FIG. 2 is an ion implanter that utilizes a ribbon beam according to one embodiment.

### DETAILED DESCRIPTION

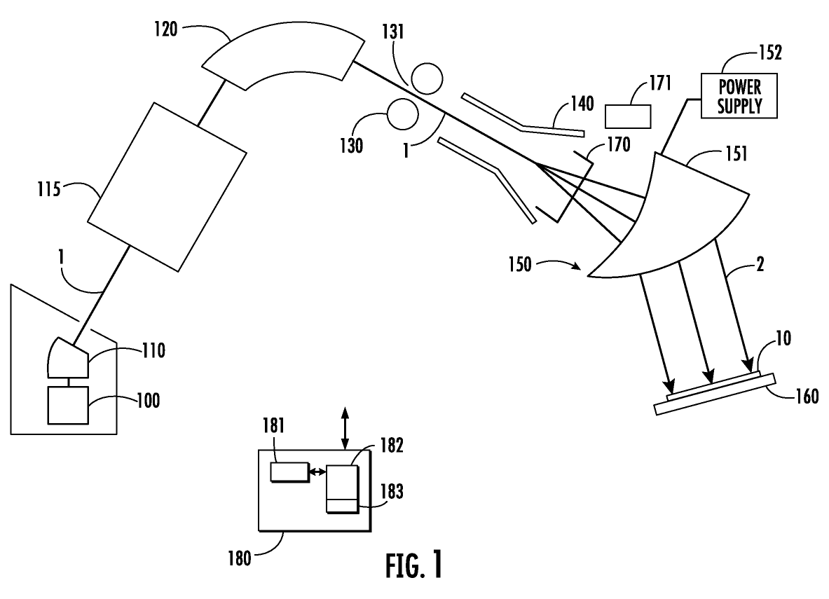

FIG. 1 shows a spot beam ion implantation system that may be used for implanting ions into a workpiece using a spot beam according to one embodiment.

The spot beam ion implantation system includes an ion source 100 comprising a plurality of chamber walls defining an ion source chamber. In certain embodiments, the ion source 100 may be an RF ion source. In this embodiment, an RF antenna may be disposed against a dielectric window. This dielectric window may comprise part or all of one of the chamber walls. The RF antenna may comprise an electrically conductive material, such as copper. An RF power supply is in electrical communication with the RF antenna. The RF power supply may supply an RF voltage to the RF antenna. The power supplied by the RF power supply may be between 0.1 and 10 kW and may be any suitable frequency, such as between 1 and 100 MHz. Further, the power supplied by the RF power supply may be pulsed.

In another embodiment, a cathode is disposed within the ion source chamber. A filament is disposed behind the cathode and energized so as to emit electrons. These electrons are attracted to the cathode, which in turn emits electrons into the ion source chamber. This cathode may be referred to as an indirectly heated cathode (IHC), since the cathode is heated indirectly by the electrons emitted from the filament.

Other embodiments are also possible. For example, the plasma may be generated in a different manner, such as by a Bernas ion source, a capacitively coupled plasma (CCP) source, microwave or ECR (electron-cyclotron-resonance) ion source. The manner in which the plasma is generated is not limited by this disclosure.

One chamber wall, referred to as the extraction plate, includes an extraction aperture. The extraction aperture may be an opening through which the ions 1 generated in the ion source chamber are extracted and directed toward a workpiece 10. The extraction aperture may be any suitable shape. In certain embodiments, the extraction aperture may be round or oval shaped.

Disposed outside and proximate the extraction aperture of the ion source 100 are extraction optics 110. In certain embodiments, the extraction optics 110 comprise one or more electrodes. Each electrode may be a single electrically conductive component with an aperture disposed therein. Alternatively, each electrode may be comprised of two electrically conductive components that are spaced apart so as to create the aperture between the two components. The electrodes may be a metal, such as tungsten, molybdenum or titanium. One or more of the electrodes may be electrically connected to ground. In certain embodiments, one or more of the electrodes may be biased using an electrode power supply. The electrode power supply may be used to bias one or more of the electrodes relative to the ion source so as to attract ions through the extraction aperture. The extraction aperture and the aperture in the extraction optics are aligned such that the ions 1 pass through both apertures. In some embodiments, the electrodes may be disposed on a movable manipulator that is configured to move the electrodes relative to the ion source 100 in one or more directions.

Located downstream from the extraction optics 110 is a mass analyzer 120. The mass analyzer 120 uses magnetic fields to guide the path of the extracted ions 1. The magnetic fields affect the flight path of ions according to their mass and charge.

An acceleration/deceleration column 115 may be positioned between the extraction optics 110 and mass analyzer 120. In some embodiments, the parameters of the acceleration/deceleration column 115 may be adjusted.

A mass resolving device 130 that has a resolving aperture 131 is disposed at the output, or distal end, of the mass analyzer 120. By proper selection of the magnetic fields, only those ions 1 that have a selected mass and charge will be directed through the resolving aperture 131. Other ions will strike the mass resolving device 130 or a wall of the mass analyzer 120 and will not travel any further in the system. The ions that pass through the mass resolving device 130 may form a spot beam.

The spot beam may then enter a scanner 140 which is disposed downstream from the mass resolving device 130. The scanner 140 causes the spot beam to be fanned out into a plurality of divergent beamlets, referred to as a scanned spot beam. The scanner 140 may be electrostatic or magnetic.

In some embodiments, the scanned spot beam enters a corrector magnet 150. The corrector magnet 150 is designed to deflect ions in the scanned spot beam to produce a scanned ion beam 2 having parallel ion trajectories, thus focusing the scanned ion beam. Specifically, the corrector magnet 150 is used to alter the diverging ion trajectory paths into substantially parallel paths of a scanned ion beam 2. In particular, the corrector magnet 150 may comprise magnetic pole pieces 151 which are spaced apart to define a gap and a magnet coil (not shown) which is coupled to a power supply 152. The scanned spot beam passes through the gap between the magnetic pole pieces 151 and is deflected in accordance with the magnetic field in the gap. The magnetic field may be adjusted by varying the current through the magnet coil. In other embodiments, a corrector magnet 150 may not be employed.

The workpiece 10 is disposed on a movable workpiece holder 160.

In certain embodiments, the direction of the scanned ion beam 2 is referred to as the Z-direction, the direction perpendicular to this direction and horizontal may be referred to as the X-direction or width direction, while the direction perpendicular to the Z-direction and vertical may be referred to as the Y-direction or height direction. In this figure, it is assumed that the scanner 140 scans the spot beam back and forth in the width direction while the movable workpiece holder 160 is translated in the height direction. In other embodiments, the scanner 140 may scan back and forth in the height direction while the movable workpiece holder 160 moves in the width direction. Thus, the direction of scan may simply be referred to as the scan direction, while the movable workpiece holder 160 moves in a second direction perpendicular to the scan direction. The rate at which the scanner 140 scans the spot beam in the scan direction may be referred to as beam scan speed or simply scan speed.

In other embodiments, the scanner 140 may be capable of scanning in both the width and height directions, either independently or simultaneously, enabling the creation of any desired scan pattern.

Thus, in operation, the movable workpiece holder 160 moves in the second direction from a first position, which may be above the scanned ion beam 2 to a second position, which may be below the scanned ion beam. The movable workpiece holder 160 then moves from the second position back to the first position. During this time, the spot beam is being scanned in the scan direction by the scanner 140, ensuring that the entirety of the workpiece 10 is exposed to the scanned ion beam 2.

Note that if the scanner 140 is capable of scanning on two directions, either independently or simultaneously, the workpiece holder may remain stationary.

A retractable current sensor 170 is located downstream from the scanner 140. In some embodiments, the retractable current sensor 170 is located immediately after the scanner 140 and before the corrector magnet 150. The retractable current sensor 170 may in connected to an actuator 171, that moves it from the retracted position to the inserted position. When the spot beam ion implantation system is in normal operation, the retractable current sensor 170 is moved out of the path of the spot beam into a retracted position. However, when the configuration and calibration procedure, also referred to as the setup procedure, is ongoing, the retractable current sensor 170 is disposed in an inserted position, which is in the path of the spot beam. The retractable current sensor 170 may be a Faraday sensor or other suitable sensor. In some embodiments, the retractable current sensor 170 may include a graphite surface that collects charge, which can then be measured.

A controller 180 is also used to control the system. The controller 180 has a processing unit 181 and an associated memory device 182. This memory device 182 contains the instructions 183, which, when executed by the processing unit, enable the system to perform the functions described herein. This memory device 182 may be any non-transitory storage medium, including a non-volatile memory, such as a FLASH ROM, an electrically erasable ROM or other suitable devices. In other embodiments, the memory device 182 may be a volatile memory, such as a RAM or DRAM. In certain embodiments, the controller 180 may be a general purpose computer, an embedded processor, or a specially designed microcontroller. The actual implementation of the controller 180 is not limited by this disclosure. The controller 180 may be in communication with the scanner 140, the retractable current sensor 170 and other components, so as to tune the spot beam ion implantation system.

During the configuration and calibration procedure, the controller 180 moves the retractable current sensor 170 to the inserted position, as shown in FIG. 1. The controller 180 then receives current measurements from the retractable current sensor 170. These current measurements are indicative of the beam current of the spot beam. In response to these current measurements, the controller 180 may adjust parameters of the ion source 100, the extraction optics 110 and other components. For example, the extraction current of the ion source, the position of the electrodes in the extraction optics and various magnet elements may be tuned to achieve the desired beam current. In some embodiments, the configuration and calibration procedure is used to maximize the beam current of the extracted spot beam. In other embodiments, the procedure may be used to tune the components to produce a spot beam having a predetermined beam current.

Unlike traditional systems in which the scanner 140 is disabled during the configuration and calibration procedure, the controller 180 also instructs the scanner 140 to scan the spot beam during the configuration and calibration procedure. The spot beam may be scanned in the scan direction at any suitable scan frequency. In some embodiments, the surface of the retractable current sensor 170 is large enough such that the spot beam, even when scanned, strikes the surface of the current sensor. The current measured by the retractable current sensor 170 are used by the controller 180 to tune the spot beam ion implantation system. In other embodiments, the surface of the retractable current sensor 170 may be smaller in the scan direction than the scanned spot beam. In these embodiments, the controller 180 may use a multiplication factor or equation to calculate the actual beam current based on the percentage of time that the scanned spot beam strikes the surface of the retractable current sensor 170. In yet another embodiment, the retractable current sensor may comprise two or more surfaces, wherein the controller 180 sums the current collected by all of the surfaces to determine the actual beam current.

Note that in this embodiment, the retractable current sensor 170 remains stationary during the configuration and calibration procedure while the spot beam is scanned. However, other embodiments that allow relative movement between the retractable current sensor 170 and the spot beam are also possible. For example, using the actuator 171, the retractable current sensor 170 may be moved back and forth in the scan direction while the scanner 140 is disabled.

In some embodiments, it is possible that the current detected by the retractable current sensor 170 when there is relative motion between the retractable current sensor and the spot beam may differ from the current detected when both the current sensor and spot beam are stationary. In certain embodiments, the controller 180 may convert the measured current into an equivalent current, which is defined as the current that would be measured if both components were stationary. This conversion may be performed using an equation or a table. Furthermore, this equation or table may be determined using a current sensor calibration process, wherein, for a plurality of different beam currents, the controller 180 measures the current when both components are stationary and when the components are moving relative to each other. Based on this data, an equation or table may be generated. This equation or table may also be generated theoretically, rather than empirically.

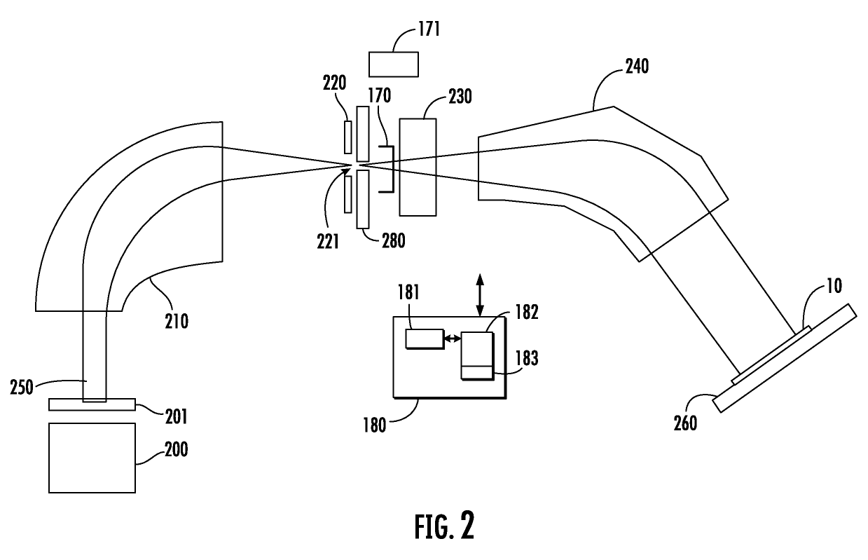

The movement of the ion beam relative to the retractable current sensor 170 during the configuration and calibration procedure may be applied to other types of ion implanters as well. FIG. 2 shows an ion implantation system that extracts a ribbon ion beam from the ion source. An ion source 200 is used to generate an ion beam 250, which is a ribbon ion beam having a width much greater than its height. The ion source 200 may be an indirectly heated cathode (IHC) ion source. Alternatively, the ion source 200 may be a capacitively coupled plasma source, an inductively coupled plasma source, a Bernas source or another source. Thus, the type of ion source is not limited by this disclosure. Disposed outside and proximate the extraction aperture of the ion source 200 is the extraction optics 201, which may comprise one or more electrodes. As described above, each electrode may be a single electrically conductive component with an aperture disposed therein. Alternatively, each electrode may be comprised of two electrically conductive components that are spaced apart so as to create the aperture between the two components. The electrodes may be a metal, such as tungsten, molybdenum or titanium. One or more of the electrodes may be electrically connected to ground. In certain embodiments, one or more of the electrodes may be biased using an electrode power supply. The electrode power supply may be used to bias one or more of the electrodes relative to the ion source 200 so as to attract ions through the extraction aperture. The extraction aperture and the aperture in the extraction optics are aligned such that the ion beam 250 pass through both apertures. In some embodiments, the electrodes may be disposed on a movable manipulator that is configured to move the electrodes relative to the ion source 200 in one or more directions.

Located downstream from the extraction optics 201 is a mass analyzer 210. The mass analyzer 210 uses magnetic fields to guide the path of the extracted ion beam. The magnetic fields affect the flight path of ions according to their mass and charge. A mass resolving device 220 that has a resolving aperture 221 is disposed at the output, or distal end, of the mass analyzer 210. By proper selection of the magnetic fields, only those ions in the ion beam 250 that have a selected mass and charge will be directed through the resolving aperture 221. Other ions will strike the mass resolving device 220 or a wall of the mass analyzer 210 and will not travel any further in the system. Note that as the paths of the ions exiting the mass analyzer 210 converge at the mass resolving device 220, such that the ion beam 250 has a narrow width at this point.

A collimator 230 may be disposed downstream from the mass resolving device 220. The collimator 230 accepts the ions from the ion beam 250 that pass through the resolving aperture 221 and creates an ion beam formed of a plurality of parallel or nearly parallel beamlets. The output, or distal end, of the mass analyzer 210 and the input, or proximal end, of the collimator 230 may be a fixed distance apart. The mass resolving device 220 is disposed in the space between these two components.

Located downstream from the collimator 230 may be an acceleration/deceleration stage 240. The acceleration/deceleration stage 240 is a beam-line lens component configured to independently control deflection, deceleration, and focus of the ion beam. For example, the acceleration/deceleration stage 240 may be an electrostatic filter (EF). The ion beam 250 that exits the acceleration/deceleration stage 240 is used to process the workpiece 10, which is disposed on a platen 260. This platen 260 may move in the height direction to allow the entirety of the workpiece 10 to be exposed to the ion beam 250.

Located downstream from the mass resolving device 220 and upstream from the collimator 230 is the retractable current sensor 170. This retractable current sensor 170 may be as described above and may be moved using an actuator 171.

Between the mass resolving device 220 and the retractable current sensor 170 may be a dithering magnet 280. The dithering magnet 280 applies magnetic fields to the ion beam 250 passing therethrough so as to cause the ion beam 250 to be deflected at various angles in the width direction. This may be performed to create a ribbon ion beam at the workpiece that has a more uniform current in the width direction.

As described above, a controller 180 may be used to control the ion implantation system. In this embodiment, the controller 180 may be in communication with the retractable current sensor 170, the ion source 200, the extraction optics 201, the dithering magnet 280 and other components.

During the configuration and calibration procedure, the controller 180 moves the retractable current sensor 170 to the inserted position, which is into the path of the ion beam 250, as shown in FIG. 2. The controller 180 then receives current measurements from the retractable current sensor 170. In response to these current measurements, the controller 180 may adjust parameters of the ion source 200, the extraction optics 201 and other components to optimize or maximize the beam current, as described above.

During the configuration and calibration procedure, the controller 180 also instructs the dithering magnet 280 to deflect the ion beam 250 in the width direction. The dithering frequency may be any suitable frequency. As described above, in some embodiments, the surface of the retractable current sensor 170 is large enough such that the ion beam 250, even when deflected, strikes the surface of the current sensor. In this embodiment, the retractable current sensor 170 remains stationary while the ribbon beam is dithered. In other embodiments, the surface of the retractable current sensor 170 may be smaller in the width direction than the dithered ion beam. In these embodiments, the controller 180 may use a multiplication factor or equation to calculate the actual beam current based on the percentage of time that the dithered ion beam strikes the surface of the retractable current sensor 170. In yet another embodiment, the retractable current sensor 170 may comprise two or more surfaces, wherein the controller 180 sums the current collected by all of the surfaces to determine the actual beam current.

However, other embodiments that allow relative movement between the retractable current sensor 170 and the ribbon beam are also possible. For example, the retractable current sensor 170 may be moved in the width direction and height direction while the dithering magnet 280 is disabled.

As described above, in some embodiments, it is possible that the current detected by the retractable current sensor 170 when there is relative motion between the retractable current sensor 170 and the ion beam may differ from the current detected when both the current sensor and ion beam are stationary. In certain embodiments, the controller 180 may convert the measured current into an equivalent current, which is defined as the current that would be measured if both components were stationary using the techniques described above.

Note that this technique may be applied to any ion implantation system that includes an ion source to generate an ion beam, a scanning component to move the ion beam in a scan direction, which may be a width direction, a height direction or both directions, and a workpiece holder. In some embodiments, this workpiece holder moves in a second direction, which is perpendicular to the scan direction and may be a height direction. In some of these ion implantation systems, there may be extraction optics to extract the ion beam from the ion source. Further, some ion implantation systems may have acceleration stages, which may be electrostatic or magnetic, including linear accelerators, tandem accelerators, and others. The acceleration stage is used to change the energy of the ion beam. In all of these embodiments, the retractable current sensor 170 may be disposed downstream from the scanning component such that, when the scanning component is actuated, the ion beam does not strike the same position on the current sensor throughput the configuration and calibration procedure. This scanning component may be an electrostatic scanner, as described with respect to FIG. 1, or a magnetic scanner, as described with respect to FIG. 2. In some embodiments, the retractable current sensor is located immediately after the scanning component, such that there are no other components between the scanning component and the retractable current sensor. As a result of the configuration and calibration procedure, the controller may use the current measurements to adjust the ion source, the acceleration stage or the extraction optics.

The embodiments described above in the present application may have many advantages. Currently, when using ion beams with high power, the graphite surface of the retractable current sensor 170 may become very hot, and may crack. Further, in some cases, the ion beam may create a hole completely through the graphite surface. By scanning the ion beam relative to the retractable current sensor, more of the graphite surface is impacted by the ion beam, so the temperature of the graphite surface is more uniform. This may reduce the likelihood of cracking. In addition, because the ion beam strikes different portions of the graphite surface, the time to burn a hole through the surface is greatly increased. For example, in certain tests, the graphite surface may last at least 10 times longer than currently achieved. Lastly, in some embodiments, there are no new hardware components that are used. Rather, the instructions in the controller 180 are modified to allow the scanner 140 or the dithering magnet 280 to be active during the configuration and calibration procedure.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An ion implantation system, comprising:
an ion source from which a spot beam is extracted;
a scanner which scans the spot beam in a scan direction to create a scanned spot beam;
a workpiece holder;
a retractable current sensor, disposed between the scanner and the workpiece holder, having a retracted position, used during normal operation and an inserted position, wherein the retractable current sensor is in a path of the spot beam and which is used during a configuration and calibration procedure; and
a controller, wherein the controller creates relative movement between the spot beam and the retractable current sensor during the configuration and calibration procedure, measures a current detected by the retractable current sensor and uses the measured current to adjust one or more components in the ion implantation system to create a spot beam having a desired beam current.

2. The ion implantation system of claim 1, wherein the controller moves the retractable current sensor to the inserted position and controls the scanner to scan the spot beam in the scan direction during the configuration and calibration procedure.

3. The ion implantation system of claim 1, wherein the retractable current sensor is attached to an actuator, and wherein the controller moves the retractable current sensor to the inserted position and controls the actuator to move the retractable current sensor in the scan direction during the configuration and calibration procedure.

4. The ion implantation system of claim 1, wherein the controller varies one or more parameters associated with the ion source based on the current detected by the retractable current sensor.

5. The ion implantation system of claim 1, further comprising extraction optics disposed outside the ion source, wherein the controller varies one or more parameters associated with the extraction optics based on the current detected by the retractable current sensor.

6. The ion implantation system of claim 1, wherein the retractable current sensor comprises a graphite surface which collects the current.

7. The ion implantation system of claim 6, wherein the scanner scans the spot beam in the scan direction during the configuration and calibration procedure and wherein the graphite surface is sufficiently large such that an entirety of the scanned spot beam strikes the graphite surface.

8. The ion implantation system of claim 6, wherein the scanner scans the spot beam in the scan direction during the configuration and calibration procedure; wherein the graphite surface has a dimension in the scan direction that is smaller than the scanned spot beam, and wherein the controller adjusts the current detected to compute an actual beam current, based on a percentage of time that the scanned spot beam strikes the graphite surface.

9. The ion implantation system of claim 1, wherein the scanner scans the spot beam in the scan direction during the configuration and calibration procedure; wherein the retractable current sensor comprises a plurality of graphite surfaces, and wherein the controller sums the current detected by each of the plurality of graphite surfaces to compute an actual beam current.

10. The ion implantation system of claim 1, wherein the controller converts the current detected by the retractable current sensor into an equivalent current, which is defined as a current detected if the spot beam and retractable current sensor were both stationary.

11. The ion implantation system of claim 1, further comprising a corrector magnet disposed between the scanner and the workpiece holder, wherein the retractable current sensor is disposed between the scanner and the corrector magnet.

12. An ion implantation system, comprising:
an ion source from which a ribbon ion beam is extracted;
a mass resolving device having a mass resolving aperture;
a dithering magnet, located downstream from the mass resolving device, which scans the ribbon ion beam in a width direction to create a dithered ion beam;
a workpiece holder;
a retractable current sensor, disposed between the dithering magnet and the workpiece holder, having a retracted position, used during normal operation and an inserted position, wherein the retractable current sensor is in a path of the ribbon ion beam and which is used during a configuration and calibration procedure; and
a controller, wherein the controller creates relative movement between the ribbon ion beam and the retractable current sensor during the configuration and calibration procedure, measures a current detected by the retractable current sensor and uses the measured current to adjust one or more components in the ion implantation system to create a ribbon ion beam having a desired beam current.

13. The ion implantation system of claim 12, wherein the controller moves the retractable current sensor to the inserted position and controls the dithering magnet to dither the ribbon ion beam during the configuration and calibration procedure.

14. The ion implantation system of claim 12, wherein the controller varies one or more parameters associated with the ion source based on the current detected by the retractable current sensor.

15. The ion implantation system of claim 12, further comprising extraction optics disposed outside the ion source, wherein the controller varies one or more parameters associated with the extraction optics based on the current detected by the retractable current sensor.

16. The ion implantation system of claim 12, wherein the retractable current sensor comprises a graphite surface which collects the current.

17. The ion implantation system of claim 16, wherein the dithering magnet dithers the ribbon ion beam in the width direction during the configuration and calibration procedure and wherein the graphite surface is sufficiently large such that an entirety of the dithered ion beam strikes the graphite surface.

18. The ion implantation system of claim 16, wherein the dithering magnet dithers the ribbon ion beam in the width direction during the configuration and calibration procedure; wherein the graphite surface has a dimension in the width direction that is smaller than the dithered ion beam, and wherein the controller adjusts the current detected to compute an actual beam current, based on a percentage of time that the dithered ion beam strikes the graphite surface.

19. The ion implantation system of claim 12, wherein the controller converts the current detected by the retractable current sensor into an equivalent current, which is defined as a current detected if the ribbon ion beam and retractable current sensor were both stationary.

20. An ion implantation system, comprising:
an ion source from which an ion beam is extracted;
a scanning component which scans the ion beam in a scan direction;
a workpiece holder that moves in a second direction perpendicular to the scan direction;
a retractable current sensor, disposed between the scanning component and the workpiece holder, having a retracted position, used during normal operation and an inserted position, wherein the retractable current sensor is in a path of the ion beam and which is used during a configuration and calibration procedure; and
a controller, wherein the controller creates relative movement between the ion beam and the retractable current sensor during the configuration and calibration procedure, measures a current detected by the retractable current sensor and adjusts at least one parameter of the ion implantation system based on the current detected.
